(19) United States
(12) Patent Application Publication
(10) Pub. No.: US 2025/0216445 A1
(43) Pub. Date: Jul. 3, 2025

(54) CHIP COOLING MODULE AND CHIP TESTING APPARATUS HAVING SAME

(71) Applicant: CHROMA ATE INC., Taoyuan City (TW)

(72) Inventors: Yu-Wei Chuang, Taoyuan City (TW); Xin-Yi Wu, Taoyuan City (TW); Jui-Che Chou, Taoyuan City (TW)

(73) Assignee: CHROMA ATE INC., Taoyuan City (TW)

(21) Appl. No.: 18/957,110

(22) Filed: Nov. 22, 2024

(30) Foreign Application Priority Data
Dec. 29, 2023 (TW) 112151739

(51) Int. Cl. G01R 31/28

(52) U.S. Cl. CPC G01R 31/2877; G01R 31/2863

(57) ABSTRACT

A chip cooling module and a chip testing apparatus having the same are provided. The chip cooling module includes a socket and a fluid supply device. The socket includes a chip slot and at least one fluid channel, and the chip slot is configured to accommodate a chip. The fluid supply device is in communication with the at least one fluid channel of the socket. The at least one fluid channel includes a divergent opening, and the divergent opening is provided on a sidewall of the socket and faces the chip slot. In response to the fluid supply device supplying a cooling fluid to the at least one fluid channel, the cooling fluid forms a jet stream toward the chip slot through the divergent opening.

### CROSS-REFERENCE TO RELATED APPLICATION

This non-provisional application claims priority under 35 U.S.C. § 119(a) to patent application Ser. No. 11/215,1739 filed in Taiwan, R.O.C. on Dec. 29, 2023, the entire contents of which are hereby incorporated by reference.

### BACKGROUND

### Technical Field

The disclosure relates to a chip cooling module suitable for cooling a testing apparatus and a chip during chip testing, and a chip testing apparatus having the same.

### Related Art

With the advancement of technology, integrated circuits (hereinafter referred to as “chips”) have become increasingly sophisticated, and their performance has been improving year by year. To ensure the yield of chips, they must undergo testing before leaving the factory to verify their proper functioning. However, as chip performance improves, their power consumption also increases accordingly. Consequently, the heat generated during chip testing gradually rises, potentially causing problems for the chip socket that houses the chip due to overheating, and ultimately leading to damage to the testing equipment.

Additionally, when the temperature of the chip under test or the probes within the chip socket exceeds 100° C., the solder balls on the bottom of the chip may begin to soften. Therefore, during the testing process, it is common for the solder balls to melt and adhere to the probe, or for solder residues to scatter within the test socket. Over time, this can lead to test failures in mild cases and short circuits in severe cases, resulting in damage to the chip or equipment failure.

### SUMMARY

To address the aforementioned problems, the present disclosure provides a chip cooling module and a chip testing apparatus having the same. The cooling fluid is generated by a fluid supply device and flows through a fluid accommodating space formed by a lower surface of a chip and a chip slot to cool the chip slot. In addition, the chip cooling module and the chip testing apparatus having the same can also direct the cooling fluid to flow over an upper surface of the chip simultaneously, to further enhancing the cooling efficiency of the chip socket.

In some embodiments, the chip cooling module includes a socket and a fluid supply device. The socket includes a chip slot and at least one fluid channel, and the chip slot is configured to accommodate a chip. The fluid supply device is in communication with the at least one fluid channel of the socket. The at least one fluid channel includes a divergent opening, and the divergent opening is provided on a sidewall of the socket and faces the chip slot. In response to the fluid supply device supplying a cooling fluid to the at least one fluid channel, the cooling fluid forms a jet stream toward the chip slot through the divergent opening. The cooling fluid is a gas

In some embodiments, in response to the chip being accommodated in the chip slot, a fluid accommodating space is formed by a lower surface of the chip and the chip slot; and in response to the fluid supply device supplying the cooling fluid to the at least one fluid channel, the cooling fluid forms a jet stream toward the fluid accommodating space through the divergent opening.

In some embodiments, the socket further includes at least one fluid discharge channel, where the at least one fluid discharge channel is arranged on another sidewall of the chip slot, one end of the at least one fluid discharge channel is connected to the chip slot, and another end of the at least one fluid discharge channel is connected to an external atmosphere; and the sidewall and the another sidewall are respectively located on two opposite sides of the chip slot.

In some embodiments, the chip cooling module further includes a socket plate, where the socket plate is arranged on the socket; the socket plate includes at least one jet stream channel, one end of the at least one jet stream channel is connected to the fluid supply device, and another end of the at least one jet stream channel is connected to the chip slot of the socket; the at least one jet stream channel includes a divergent jet opening, and the divergent jet opening is provided on the sidewall of the socket and faces the chip slot; and in response to the fluid supply device supplying the cooling fluid to the at least one jet stream channel, the cooling fluid forms a jet stream toward the chip slot through the divergent jet opening.

In some embodiments, the chip testing apparatus includes a socket, a fluid supply device, and a controller. The socket includes a chip slot and at least one fluid channel, where the chip slot is configured to accommodate a chip, the at least one fluid channel includes a divergent opening, and the divergent opening is provided on a sidewall of the socket and faces the chip slot. The fluid supply device is in communication with the at least one fluid channel of the socket. The controller is electrically connected to the socket and the fluid supply device. The controller is configured to control the fluid supply device to supply a cooling fluid to the at least one fluid channel, such that the cooling fluid forms a jet stream toward the chip slot when flowing through the divergent opening, and the controller is configured to control the socket to test the chip. The cooling fluid is a gas.

In some embodiments, the chip testing apparatus further includes a socket plate, and the socket plate is arranged on the socket. The socket plate includes at least one jet stream channel, one end of the at least one jet stream channel is connected to the fluid supply device, and another end of the at least one jet stream channel is connected to the chip slot of the socket, where the at least one jet stream channel includes a divergent jet opening. The controller is further configured to control the fluid supply device to supply the cooling fluid to the at least one jet stream channel, such that the cooling fluid forms a jet stream toward the chip slot through the divergent jet opening.

In some embodiments, the chip testing apparatus further includes a workpress, where the workpress corresponds to the chip slot of the socket and is electrically connected to the controller, and the controller is further configured to control the workpress to approach the chip slot to press against the chip or control the workpress to move away from the chip slot. The workpress includes an outlet channel and a pressing surface, the pressing surface includes a flow-guiding groove, and the flow-guiding groove is in communication with the divergent jet opening of the socket, where one end of the outlet channel is in communication with the flow-guiding groove, and another end of the outlet channel is in communication with an external atmosphere.

In some embodiments, the chip testing apparatus further includes a workpress, where the workpress corresponds to the chip slot of the socket and is electrically connected to the controller, and the controller is further configured to control the workpress to approach the chip slot to press against the chip or control the workpress to move away from the chip slot. The workpress includes at least one top flow channel, the at least one top flow channel is in communication with the fluid supply device, the at least one top flow channel includes a divergent outlet, and the divergent outlet faces the chip slot; and the controller is further configured to control the fluid supply device to supply the cooling fluid to the at least one top flow channel, such that the cooling fluid forms a jet stream toward the chip slot through the divergent outlet.

In summary, according to any one of the embodiments described above, the chip cooling module and the chip testing apparatus having the same may provide a cooling fluid to a chip slot through a fluid channel on a sidewall of a socket to cool the chip slot. When the cooling fluid passes through a divergent opening of the fluid channel, a pressure and a temperature of the fluid decrease, while a flow velocity of the cooling fluid increases, to form a jet stream toward the chip slot. In this way, the cooled cooling fluid can cool the interior of the chip slot. In addition, the cooling fluid may also be synchronously provided to the chip slot through a jet stream channel on the sidewall of the socket or a top flow channel of a workpress, thereby further enhancing the cooling effect of the chip slot.

### BRIEF DESCRIPTION OF THE DRAWINGS

FIG. 1 is a perspective view of a chip testing apparatus according to an embodiment;

FIG. 2 is an exploded perspective view of the chip testing apparatus according to an embodiment;

FIG. 3 is a system block diagram of the chip testing apparatus according to an embodiment;

FIG. 4 is a schematic diagram of the chip testing apparatus according to an embodiment;

FIG. 5 is a cross-sectional view taken along a cross-sectional line 5-5 of FIG. 1;

FIG. 6 is an enlarged cross-sectional view of a circled region in FIG. 5;

FIG. 7 is a cross-sectional view taken along a cross-sectional line 7-7 of FIG. 1;

FIG. 8 is a schematic cross-sectional view taken along a cross-sectional line 9-9 of FIG. 1;

FIG. 9 is a schematic cross-sectional view taken along a cross-sectional line 10-10 of FIG. 1;

FIG. 10 is a schematic diagram of the chip testing apparatus according to another embodiment; and

FIG. 11 is a cross-sectional view of the chip testing apparatus according to another embodiment.

### DETAILED DESCRIPTION

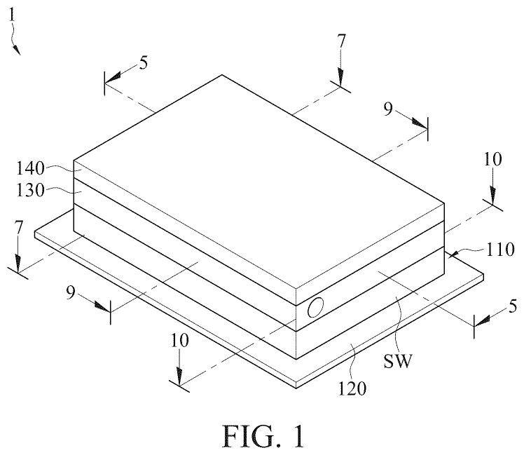

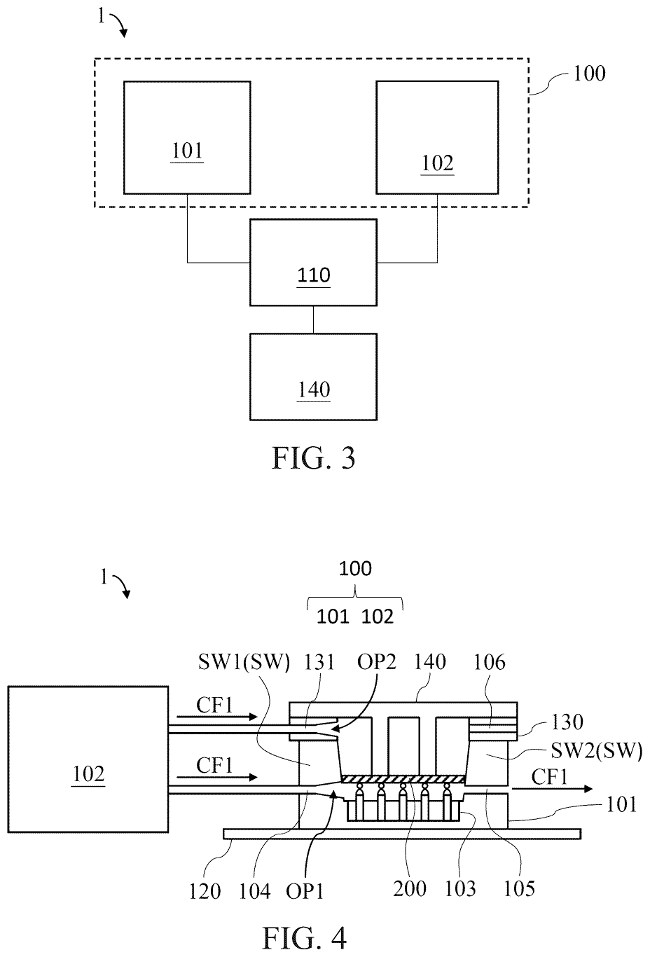

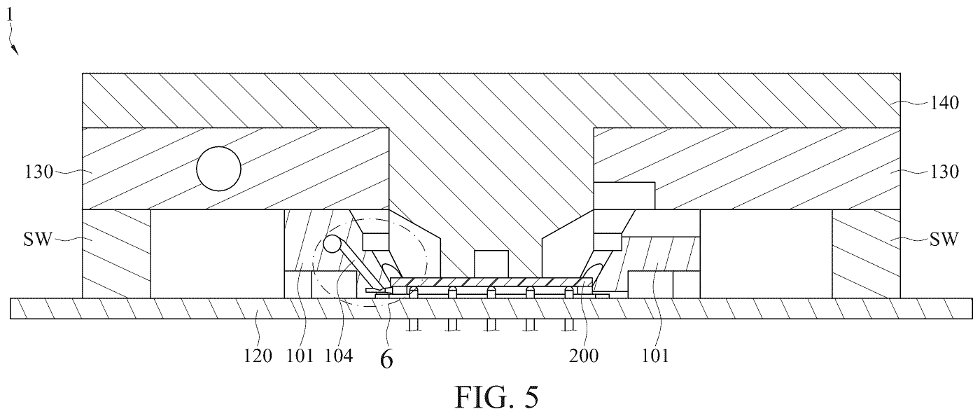

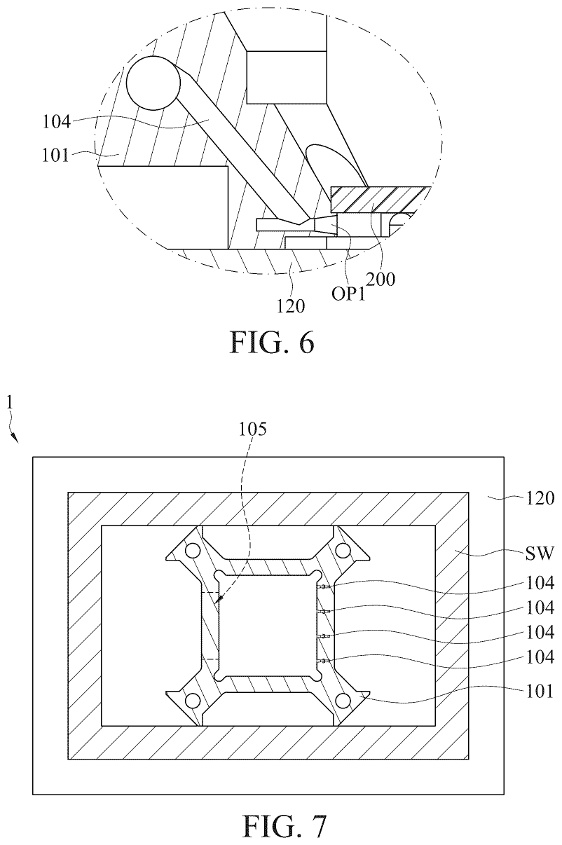

Referring to FIG. 1 to FIG. 7, a chip testing apparatus 1 includes a chip cooling module 100 and a controller 110. The chip cooling module 100 includes a socket 101 and a fluid supply device 102. The socket 101 includes a chip slot 103 and a fluid channel 104. The chip slot 103 is configured to accommodate a chip 200, and the fluid supply device 102 is connected to the fluid channel 104 of the socket 101. In some embodiments, the socket 101 further includes sidewalls SW, wherein the side walls SW define the chip socket 103 such that when the chip under test 200 is placed on the chip socket 103, it is secured by the side walls SW (as shown in FIG. 4). (as shown in FIG. 4).

In some embodiments, the chip testing apparatus 1 further includes a testing circuit board 120. The socket 101 is arranged on the testing circuit board 120. As shown in FIG. 4, in some embodiments, the controller 110 is electrically connected to the socket 101 and the fluid supply device 102. In some embodiments, the testing circuit board 120 may be a dedicated testing board exclusive to the chip 200, for example, but not limited to, a development board, a motherboard, or a general-purpose test board. That is, when the chip 200 is changed, the testing circuit board 120 will be replaced accordingly.

FIG. 7 shows four fluid channels 104, but is not limited thereto. In addition, as shown in FIG. 4 to FIG. 6, each fluid channel 104 includes a divergent opening OP1. The divergent opening OP1 is provided on a sidewall SW1 of the socket 101, and the divergent opening OP1 is directed towards the chip slot 103. In some embodiments, the chip slot 103 is provided with a plurality of pogo pings, which correspond to a plurality of pins or a plurality of solder balls on a lower surface of the chip 200. When the chip 200 is placed in the chip slot 103, the chip 200 is electrically contacted with the plurality of pogo pings of the chip slot 103 through the plurality of pins or the plurality of solder balls. Furthermore, a fluid accommodating space is formed by the lower surface of the chip 200 and the chip slot 103, and the divergent opening OP1 is directed towards the fluid accommodating space.

In some embodiments, the socket 101 further includes a fluid discharge channel 105 arranged on the another sidewall SW2 of the chip slot 103. One end of the fluid discharge channel 105 is connected to the fluid accommodating space of the chip slot 103, while the other end is open to the external atmosphere. In some embodiments, the fluid discharge channel 105 may be a single elongated discharge channel or multiple independent discharge channels, with no interconnection between the independent discharge channels.

As shown in FIG. 4, in some embodiments, the chip testing apparatus 1 further includes a socket plate 130 and a workpress 140. The socket plate 130 is positioned on top of the socket 101. The workpress 140 is aligned above the chip slot 103 of the socket 101, and may include a lifting mechanism (not shown in the figure), which may include but is not limited to a pneumatic cylinder, hydraulic cylinder, linear motor, screw jack, or other equivalent mechanisms. In addition, the workpress 140 is electrically connected to the controller 110, and the controller 110 may control the lifting and lowering of the workpress 140.

In some embodiments, when the chip testing apparatus 1 begins operation, the controller 110 controls the workpress 140 to approach the chip slot 103 and press against the chip 200, ensuring that the plurality of solder balls of the chip 200 are electrically contacted with the plurality of pogo pings of the chip slot 103. When the workpress 140 presses against the chip 200, a fluid chamber is formed by the workpress 140, the socket 101, and the socket plate 130.

In some embodiments, the controller 110 controls the fluid supply device 102 to generate a cooling fluid CF1 and supply it to the fluid channel 104, causing the fluid channel 104 forms a jet stream toward the chip slot 103 through the divergent opening OP1. Further, when the cooling fluid CF1 is supplied to the fluid channel 104 and flows into the divergent opening OP1, since the divergent opening OP1 is configured as a divergent nozzle, the cooling fluid CF1 is ejected toward an outlet direction of the divergent opening OP1. As the cooling fluid CF1 passes through the divergent opening OP1, its velocity significantly increases, while both its temperature and pressure decrease considerably. The cooling fluid CF1 with reduced temperature can then cool the chip 200 and the chip slot 103.

Further, as shown in FIG. 4, when the cooling fluid CF1 flows into the fluid accommodating space formed by the lower surface of the chip 200 and the chip slot 103, and then the cooling fluid CF1 flows out of the fluid accommodating space through the fluid discharge channel 105. In this case, since the cooling fluid CF1 passes over the lower surface of the chip 200 (including the pins or the solder balls) and the chip slot 103 (including the pogo pings), it is able to cool both the chip 200 and the chip slot 103. In addition, since the cooling fluid CF1 flows through the fluid accommodating space at a certain flow velocity, it can carry away debris or dust from the fluid accommodating space and discharge these foreign particles through the fluid discharge channel 105, thereby maintaining the cleanliness of the chip slot 103.

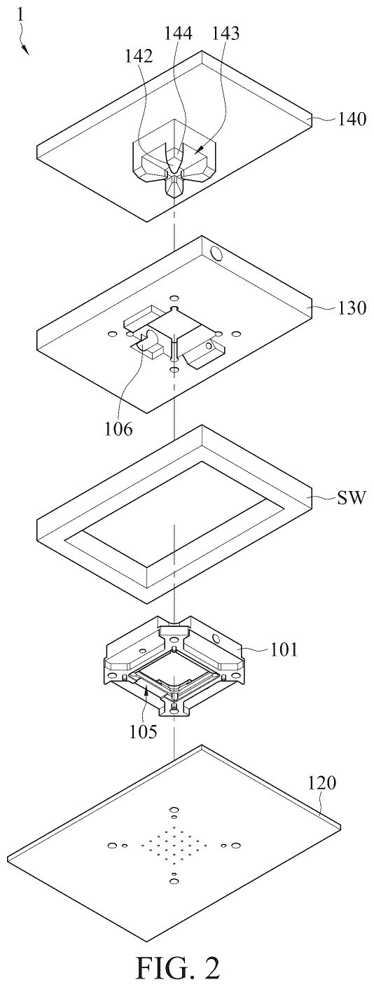

Referring to FIG. 2, the workpress 140 includes four pressing blocks 144, which are evenly distributed on a lower surface of the workpress 140. Each pressure block 144 includes a pressing surface 142, configured to press against the chip 200, ensuring that all the pins or solder balls on the chip 200 are electrically connected to the corresponding pogo pins on the chip slot 103 of the socket 101. Further, the gaps between the four pressing blocks 144 form the flow-guiding grooves 143.

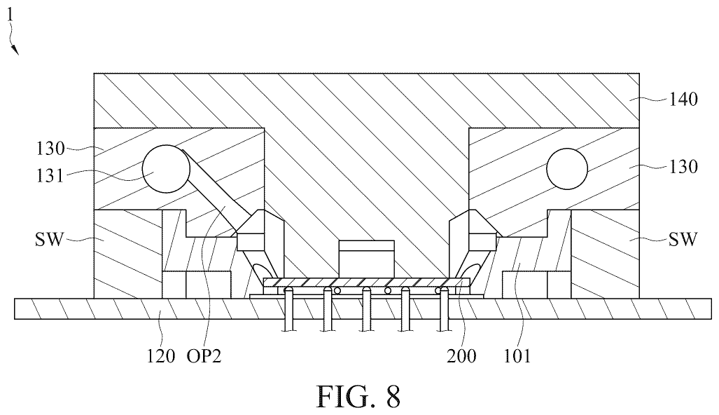

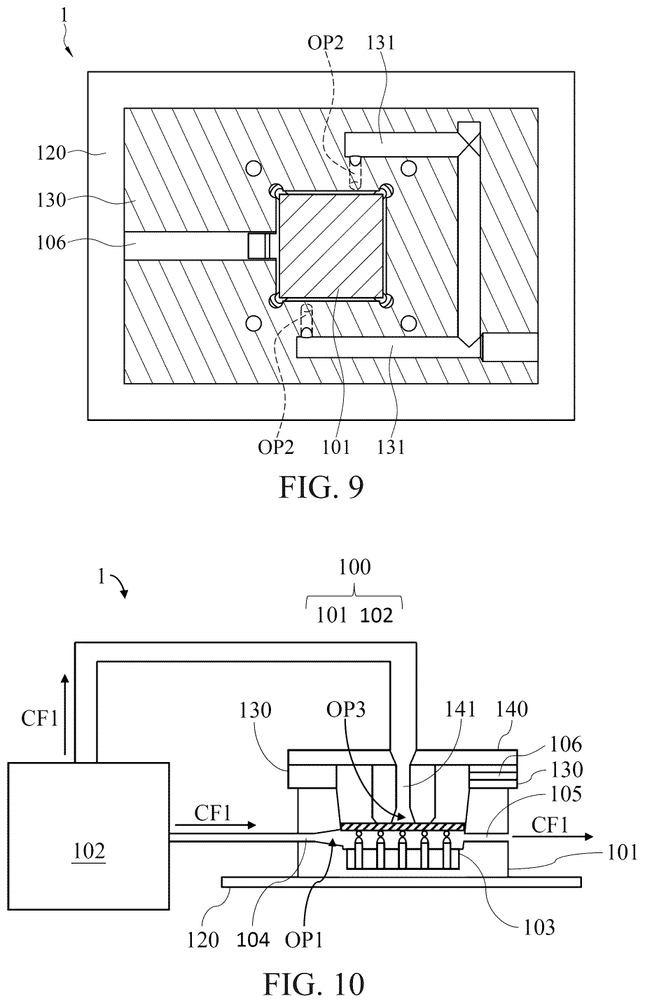

As shown in FIG. 2, FIG. 4, FIG. 8, and FIG. 9, the socket plate 130 includes two jet stream channels 131, with one end connected to the fluid supply device 102 and the other end connected to the chip slot 103 of the socket 101. In addition, an outlet channel 106 is provided on the sidewall SW of the socket 101, with one end connected to the chip slot 103 and the other end connected to an external atmosphere.

In some embodiments, the jet stream channel 131 includes a divergent jet opening OP2, with an opening direction obliquely downward and towards the chip 200. In this way, when the fluid supply device 102 supplies the cooling fluid CF1 to the jet stream channel 131, the cooling fluid CF1 forms a jet stream toward the chip slot 103 through the divergent jet opening OP2 to cool the chip 200, and then is discharged through the outlet channel 106.

Further, since the divergent jet opening OP2 is also configured as a divergent nozzle, when the cooling fluid CF1 is supplied to the jet stream channel 131 and enters the divergent jet opening OP2, the flow velocity of the cooling fluid CF1 significantly increases due to the structure of the nozzle, while both its temperature and pressure drop considerably. However, the cooling fluid CF1 with reduced temperature can effectively cool the upper surface of the chip 200. In addition, the flow-guiding grooves 143 on the workpress 140 provides the flow paths for the cooling fluid CF1.

Further, as shown in FIG. 4 and FIG. 8, when the workpress 140 presses against the chip 200, the workpress 140, the socket 101, and the socket plate 130 form a fluid chamber. This fluid chamber is divided into upper and lower fluid accommodating spaces by the chip 200. Therefore, after the fluid supply device 102 supplies the cooling fluid CF1 to the fluid channel 104 and the jet stream channel 131 simultaneously, and after accelerating and cooling the cooling fluid CF1 through the divergent opening OPI and the divergent jet opening OP2, the cooling fluid CF1 may flow into the upper and lower fluid accommodating spaces of the chip 200 respectively. Thereby, in addition to cooling the upper and lower surfaces of the chip 200, the internal space of the chip slot 103 can also be cleaned simultaneously to avoid dust, lint, or other contaminants from affecting the test.

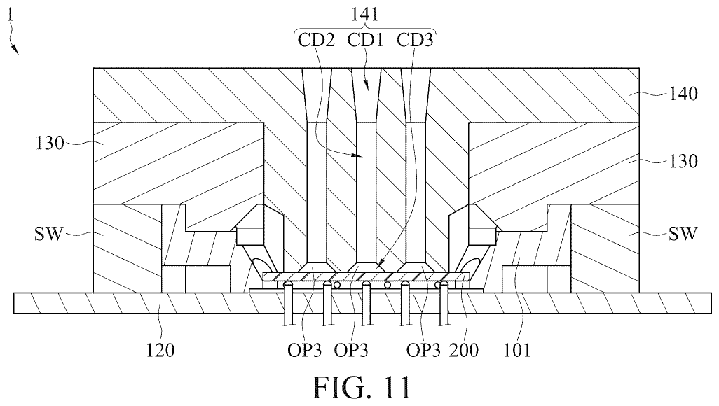

Referring to FIG. 10 and FIG. 11, in an embodiment shown in the figure, the workpress 140 may include a top flow channel 141, with one end connected to the fluid supply device 102 and the other end including a divergent outlet OP3 with its opening directed toward the chip 200. Accordingly, when the fluid supply device 102 supplies the cooling fluid CF1 to the top flow channel 141, and the cooling fluid CF1 is accelerated and cooled through the divergent outlet OP3, the upper surface of the chip 200 may be cooled. It should be noted that only one top flow channel 141 is shown in FIG. 10, but is not limited thereto. In other embodiments, a plurality of top flow channels 141 may be included, as the embodiment shown in FIG. 11. In addition, the number and positioning of the top flow channels 141 can be configured in conjunction with the pressing blocks 144 and the flow-guiding grooves 143 located beneath the workpress 140, as shown in FIG. 2.

In addition, in the embodiment shown in FIG. 11, the top flow channel 141 includes a convergent section CD1, a neck section CD2, and a divergent section CD3. The convergent section CD1 is connected to the fluid supply device 102, the neck section CD2 is located between the convergent section CD1 and the divergent section CD3, and the divergent section CD3 includes the divergent outlet OP3. When the cooling fluid CF1 flows through the convergent section CD1, the flow velocity of the fluid significantly increases, while the temperature and the pressure both greatly decrease. Then, when the cooling fluid CF1 flows through the neck section CD2, the velocity of the fluid slightly increases, and the temperature and the pressure slightly decrease. Finally, when the cooling fluid CF1 enters the divergent section CD3, the flow velocity of the fluid sharply increases, and the temperature and the pressure both sharply decrease. Therefore, in the embodiment shown in FIG. 11, the temperature of the cooling fluid CF1 can be significantly reduce. Particularly, the fluid channel 104 and the jet stream channel 131 mentioned in the foregoing embodiments may also adopt the configuration of the convergent section CD1, the neck section CD2, and the divergent section CD3.

In some embodiments, when the cooling fluid CF1 forms a jet stream toward the chip slot 103 through the divergent opening OP1, the divergent jet opening OP2, and the divergent outlet OP3, a temperature of the jet stream formed by the cooling fluid CF1 is lower than its initial temperature. Referring to Table 1, which presents actual experimental data showing the temperature of the jet stream formed by the cooling fluid CF1 at different fluid pressures. As shown in Table 1, the initial temperature of the cooling fluid CF1 is 20° C. When the fluid pressure provided by the fluid supply device 102 is 0.62 MPa, the temperature of the jet stream formed by the cooling fluid CF1 is 10.1° C. That is, when the cooling fluid CF1 flows through the divergent opening OP1 or the divergent jet opening OP2, the temperature may decrease by about 10° C. When the fluid pressure provided by the fluid supply device 102 is 0.75 MPa, the temperature of the jet stream formed by the cooling fluid CF1 further decreases to 8.2° C. Therefore, the greater the fluid pressure provided by the fluid supply device 102, the lower the temperature of the cooling fluid CF1 as it flows through the divergent opening OP1 or the divergent jet opening OP2.

TABLE 1

| | | |
|---|---|---|
| Fluid pressure (MPa) | 0.62 | 0.75 |
| Initial temperature of | 20 | 20 |
| cooling fluid(° C.) | | |
| Temperature of jet | 10.1 | 8.2 |
| stream in chip slot(° C.) | | |

In an additional computer simulation, the simulation conditions include: the initial temperature of the cooling fluid CF1 is 20° C., and a thermal design power (TDP) of the chip 200 is 8 W; and when the cooling fluid CF1 with a mass flow rate of 0.0092 kg/s is provided to the top flow channel 141 shown in FIG. 11, the fluid temperature of the divergent outlet OP3 may reach 3.83° C., while the temperature of the cooled chip 200 is 32.18° C. In contrast, without the configuration of the convergent section CD1, the neck section CD2, and the divergent section CD3, the fluid temperature reaches 32.13° C., and the temperature of the chip 200 reaches 61.44° C.

In some embodiments, the cooling fluid CF1 may be air or gases such as, but not limited to, nitrogen, oxygen, or argon. In other embodiments, the cooling fluid CF1 may be a liquid having both high thermal conductivity and insulating properties, for example, but not limited to, an engineered fluid, deionized water, ethylene glycol, propylene glycol, or a liquid coolant, or a two-phase gas-liquid mixed fluid. It should be noted that, in some embodiments, “low temperature” represents a temperature lower than a room temperature or even a lower temperature. The room temperature is, for example, but not limited to, 25° C.

In some embodiments, the controller 110 can be a hardware component having a control function, such as, but not limited to, a central processing unit (CPU), a microprocessor, a digital signal processor (DSP), a complex programmable logic device (CPLD), a field programmable gate array (FPGA), an application specific integrated circuit (ASIC), or a microcontroller unit (MCU). Additionally, the controller 110 can also be any single or multiple processor computing device or system capable of executing computer-readable instructions, such as, but not limited to: a workstation, a laptop computer, a client terminal, a server, a distributed computing system, a handheld device, or any other computing system or device. In its most basic configuration, the controller 110 may include at least one processor and system memory.

Although the present disclosure has been described in considerable detail with reference to certain preferred embodiments thereof, the disclosure is not for limiting the scope. Persons having ordinary skill in the art may make various modifications and changes without departing from the scope and spirit of the present disclosure. Therefore, the scope of the appended claims should not be limited to the description of the preferred embodiments described above.

What is claimed is:

1. A chip cooling module, comprising:
a socket, comprising a chip slot and at least one fluid channel, wherein the chip slot is configured to accommodate a chip; and
a fluid supply device, in communication with the at least one fluid channel of the socket, wherein
the at least one fluid channel comprises a divergent opening, and the divergent opening is provided on a sidewall of the socket and faces the chip slot;
in response to the fluid supply device supplying a cooling fluid to the at least one fluid channel, the cooling fluid forms a jet stream toward the chip slot through the divergent opening; and
the cooling fluid is a gas.

2. The chip cooling module according to claim 1, wherein in response to the chip being accommodated in the chip slot, a fluid accommodating space is formed by a lower surface of the chip and the chip slot; and
in response to the fluid supply device supplying the cooling fluid to the at least one fluid channel, the cooling fluid forms the jet stream toward the fluid accommodating space through the divergent opening.

3. The chip cooling module according to claim 1, wherein the socket further comprises at least one fluid discharge channel, wherein the at least one fluid discharge channel is arranged on another sidewall of the chip slot, one end of the at least one fluid discharge channel is connected to the chip slot, and another end of the at least one fluid discharge channel is connected to an external atmosphere; and
the sidewall and the another sidewall are respectively located on two opposite sides of the chip slot.

4. The chip cooling module according to claim 1, further comprising a socket plate, wherein the socket plate is arranged on the socket;
the socket plate comprises at least one jet stream channel, one end of the at least one jet stream channel is connected to the fluid supply device, and another end of the at least one jet stream channel is connected to the chip slot of the socket;
the at least one jet stream channel comprises a divergent jet opening, and the divergent jet opening is provided on the sidewall of the socket and faces the chip slot; and
in response to the fluid supply device supplying the cooling fluid to the at least one jet stream channel, the cooling fluid forms the jet stream toward the chip slot through the divergent jet opening.

5. A chip testing apparatus, comprising:
a socket, comprising a chip slot and at least one fluid channel, wherein the chip slot is configured to accommodate a chip, the at least one fluid channel comprises a divergent opening, and the divergent opening is provided on a sidewall of the socket and faces the chip slot;
a fluid supply device, in communication with the at least one fluid channel of the socket; and
a controller, electrically connected to the socket and the fluid supply device, wherein
the controller is configured to control the fluid supply device to supply a cooling fluid to the at least one fluid channel, such that the cooling fluid forms a jet stream toward the chip slot when flowing through the divergent opening, and the controller is configured to control the socket to test the chip; and
the cooling fluid is a gas.

6. The chip testing apparatus according to claim 5, wherein in response to the chip being accommodated in the chip slot, a lower surface of the chip and the chip slot; and
in response to the fluid supply device supplying the cooling fluid to the at least one fluid channel, the cooling fluid forms the jet stream toward the fluid accommodating space through the divergent opening.

7. The chip testing apparatus according to claim 6, wherein the socket further comprises at least one fluid discharge channel, wherein the at least one fluid discharge channel is arranged on another sidewall of the chip slot, one end of the at least one fluid discharge channel is connected to the chip slot, and another end of the at least one fluid discharge channel is connected to an external atmosphere; and
the sidewall and the another sidewall are respectively located on two opposite sides of the chip slot.

8. The chip testing apparatus according to claim 5, further comprising a socket plate, wherein the socket plate is arranged on the socket;
the socket plate comprises at least one jet stream channel, one end of the at least one jet stream channel is connected to the fluid supply device, and another end of the at least one jet stream channel is connected to the chip slot of the socket, wherein the at least one jet stream channel comprises a divergent jet opening; and
the controller is further configured to control the fluid supply device to supply the cooling fluid to the at least one jet stream channel, such that the cooling fluid forms the jet stream toward the chip slot through the divergent jet opening.

9. The chip testing apparatus according to claim 8, further comprising a workpress, wherein the workpress corresponds to the chip slot of the socket and is electrically connected to the controller, and the controller is further configured to control the workpress to approach the chip slot to press against the chip or control the workpress to move away from the chip slot, wherein
the workpress comprises an outlet channel and a pressing surface, the pressing surface comprises a flow-guiding groove, and the flow-guiding groove is in communication with the divergent jet opening of the socket, wherein one end of the outlet channel is in communication with the flow-guiding groove, and another end of the outlet channel is in communication with an external atmosphere.

10. The chip testing apparatus according to claim 5, further comprising a workpress, wherein the workpress corresponds to the chip slot of the socket and is electrically connected to the controller, and the controller is further configured to control the workpress to approach the chip slot to press against the chip or control the workpress to move away from the chip slot, wherein
the workpress comprises at least one top flow channel, the at least one top flow channel is in communication with the fluid supply device, the at least one top flow channel comprises a divergent outlet, and the divergent outlet faces the chip slot; and
the controller is further configured to control the fluid supply device to supply the cooling fluid to the at least one top flow channel, such that the cooling fluid forms the jet stream toward the chip slot through the divergent outlet.
